(19) United States
(12) Patent Application Publication
(10) Pub. No.: US 2004/0178412 A1
(43) Pub. Date: Sep. 16, 2004

(54) Thin film transistor and method of manufacturing the same and display apparatus using the transistor

(76) Inventors: Chien-Ting Lai, Miao-Li (TW); Jia-Pang Pang, Miao-Li (TW); Yung-Chang Chen, Santa Clara, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/801,828

(22) Filed: Mar. 15, 2004

(30) Foreign Application Priority Data
Mar. 14, 2003 (TW) 92105710

(51) Int. Cl. H01L 29/06

(52) U.S. Cl. 257/72

(57) ABSTRACT

A thin film transistor includes a substrate (1), a gate electrode (2) disposed in the substrate, a gate insulation layer (4) disposed on the substrate and gate electrode, a channel layer (5) disposed on the gate insulation layer, a source ohmic contact layer (6a) and a drain ohmic contact layer (6b) arranged on the channel layer and at the end of the channel layer, a source electrode (7a) disposed on the substrate and source ohmic contact layer, a drain electrode (7b) disposed on the substrate and drain ohmic contact layer.

### BACKGROUND OF THE INVENTION

1. Field of the Invention

The present invention relates to a thin film transistor (TFT), and particularly to a thin film transistor used in a display device.

2. Description of Related Art

A conventional TFT disclosed by U.S. Pat. No. 5,349,205 is shown in FIG. 14. The TFT 100 comprises a substrate 10, a gate electrode 20 formed on the substrate 10, a gate protection layer 30 covering the gate electrode 20, a gate insulation layer 40 arranged on the substrate 10 and the gate protection layer 30, an amorphous silicon layer 50 formed on the gate insulation layer 40, two phosphor-doped amorphous silicon layers 60a and 60b arranged on the two sides of the amorphous silicon layer 50, a source electrode 70a formed on the phosphor-doped amorphous silicon layer 60a and the gate insulation layer 40, and a drain electrode 70b formed on the phosphor-doped amorphous silicon layer 60b and the gate insulation layer 40.

The cross-section of the gate electrode 20 is in a shape of rectangle. Each of the gate insulation layer 40, the amorphous silicon layer 50 has two opposite incline surfaces. Each of the two phosphor-doped amorphous silicon layers 60a, 60b, the source electrode 70a, and the drain electrode 70b has an incline surface.

These incline surfaces are produced in the process of deposit, spray or plating. But, a flat surface is better for attaining a good character of coating. So we do my best to flatten the incline surfaces.

In a closed circuit composed of resistance and a capacitance, a RC delay is produced, which delay the signal transmission therein. For lowering the RC delay, methods can be used as follows: Firstly, using a low impedance material to make the gate electrode 20, such as Al, Cr, Ta, its alloy, and so on; Secondly, increasing the thickness and width of the gate electrode 20 to enlarge its cross-section area. Increasing the width of the gate electrode 20 reduces the aperture ratio of the liquid crystal display, which lowers the light output efficiency. Furthermore, increasing the thickness of the gate electrode 20 makes the incline surface steeper and lowers the character of coating.

### SUMMARY OF THE INVENTION

An object of the present invention is to reduce an RC delay of a scanning signal in a TFT.

In order to achieve the object set forth, a TFT includes a substrate, a gate electrode disposed in the substrate, a gate insulation layer disposed on the substrate and gate electrode, a channel layer disposed on the gate insulation layer, a source ohmic contact layer and a drain ohmic contact layer arranged on the channel layer and at the end of the channel layer, a source electrode disposed on the substrate and source ohmic contact layer, a drain electrode disposed on the substrate and drain ohmic contact layer.

Because of the gate electrode disposed in the substrate, it is easy to increase the thickness of the gate electrode. In other words, it is easy to reduce the resistance of the gate electrode. So the present invention can overcome the above described disadvantage.

Other objects, advantages and novel features of the invention will become more apparent from the following detailed description when taken in conjunction with the accompanying drawings.

### BRIEF DESCRIPTION OF THE DRAWINGS

FIG. 1 is a cross-section view of a TFT according to the present invention;

FIG. 2 is a diagrammatic view of a display device using the TFT as shown in FIG. 1;

FIG. 3 is a cross-section view of the display device as shown in FIG. 2;

FIG. 4 to FIG. 9 indicate the processes of producing a gate electrode of the TFT as shown in FIG. 1;

FIG. 10 to FIG. 13 indicate the latter processes of manufacturing the TFT as shown in FIG. 1; and

FIG. 14 is a cross-section view of a conventional TFT.

### DETAILED DESCRIPTION OF THE INVENTION

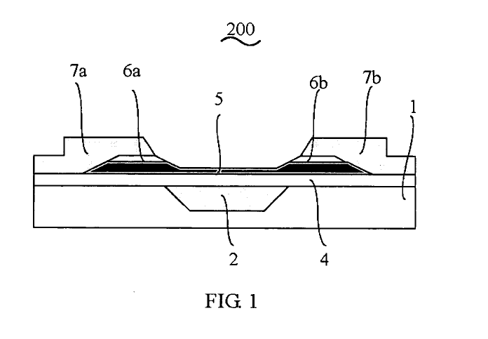

Referring to FIG. 1, there is a cross-section view of a TFT according to a first embodiment of the present invention. The TFT 200 includes a substrate 1, a gate electrode 2 disposed in the substrate 1, a gate insulation layer 4 disposed on the substrate 1 and the gate electrode 2, a channel layer 5 disposed on the gate insulation layer 4, a source ohmic contact layer 6a and a drain ohmic contact layer 6b arranged on two ends of the channel layer 5 respectively, a source electrode 7a disposed on the substrate 1 and the source ohmic contact layer 6a, a drain electrode 7b disposed on the substrate 1 and drain ohmic contact layer 6b.

The surface of the gate electrode 2 is parallel with the surface of the substrate 1. The substrate 1 can be made from glass or silicon oxide. The material of the gate electrode 2 can be metal conductive material, such as, Cu, Al, Ti, Mo, Cr, Nd, Ta, or its alloy, and so on. The gate insulation layer 4 can be made of silicon nitride or silicon oxide. The channel layer 5 can use amorphous silicon or polycrystalline silicon. The ohmic contact layer 6a and 6b can adopt amorphous silicon or phosphor-doped polycrystalline silicon. The surface of the gate electrode 2 is parallel with the surface of the substrate.

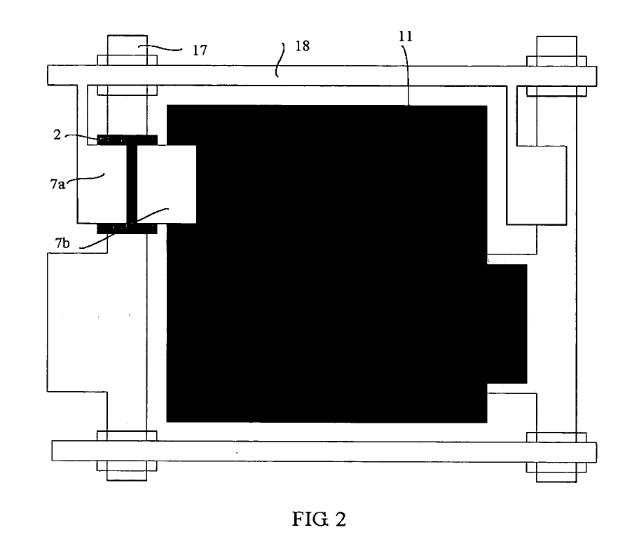

Referring to FIG. 2, there is a diagrammatic view of a display device using the TFT 100 according to a second embodiment of the present invention. The gate electrode 2 is contacted with a scanning line 17, and the source electrode 7a is contacted with a signal line 18, and the drain electrode 7b is contacted with a pixel electrode 11. The gate electrode 2 receives a signal transported by the scanning line 17. A signal transported by the signal line 18 is received by the source electrode 7a, and then output by the drain electrode 7b to the pixel electrode 11. The pixel electrode 11 holds the potential depending on a storage capacitance (not shown) until the gate electrode 2 next operation.

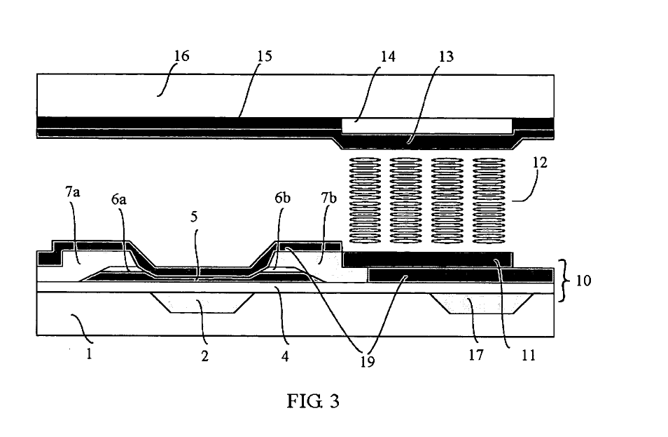

Referring to FIG. 3, there is a cross-section view of a display device as shown in FIG. 2. A protection layer 19 is formed on the thin film transistor. The pixel electrode 11 is formed on the protection layer 19 and drain electrode 7b. The storage capacitance comprises the pixel electrode 11, the gate insulation layer 4, the protection layer 19, and the scanning line 17. A color filter 14 and a black matrix 15 are formed on a substrate 16. A common electrode 13 is formed on the color filter 14 and the black matrix 15. A liquid crystal layer 12 is arranged between the pixel electrode 11 and the common electrode 13. The display device is driven by the TFT, so the display efficiency is decided by the potential of the pixel electrode 11.

Because of the gate electrode 2 is deposited in the substrate 1, the thickness of the gate electrode 2 can be changed with the depth of the substrate 1 etched. Thus it is easy to increase the thickness of the gate electrode 2 to reduce the its impedance. Furthermore, the height of the gate electrode 2 can almost be equal to that of the substrate. Therefore, the TFT 100 can efficiently reduce a RC delay of a scanning signal.

A method of producing the thin film transistor as shown in FIG. 1 comprises: a photo mask process of producing the gate electrode 2, and a latter processes of manufacturing the thin film transistor.

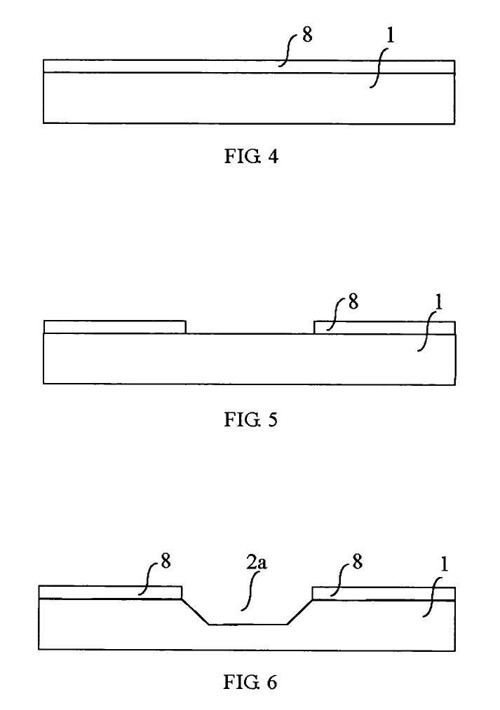

The photo mask processes of producing the gate electrode 2 shown in FIG. 4 to FIG. 9 have steps as follows:

Firstly, as shown in FIG. 4, coating a photo-resist film 8 on a substrate 1, and baking the photo-resist film 8;

Secondly, as shown in FIG. 5, using an ultraviolet light to expose the photo-resist film 8 through a photo mask having a predetermined pattern by projection manner, and then forming a pattern by developing;

Thirdly, as shown in FIG. 6, forming a slot 2a on the substrate 1 by method of dry etching or wet etching;

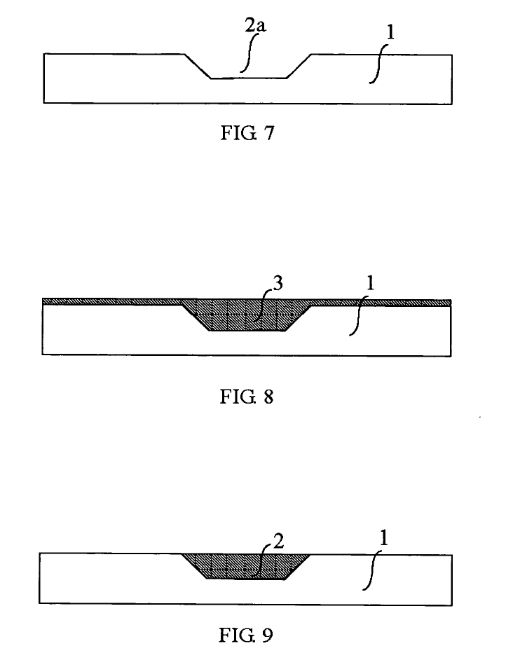

Fourthly, as shown in FIG. 7, wiping off the residual of the photo-resist film 8 by a method of dissolving, oxidizing, or directly peeling off;

And then, as shown in FIG. 8, depositing a metal layer 3 on the substrate 1 to fill the slot 2a;

Lastly, as shown in FIG. 9 , wiping off the metal on the substrate 1 by polishing to form a gate electrode 2, and the gate electrode 2 fills the slot 2a.

Some changes can be made in the former process of producing the gate electrode 2. Such as:

omitting the step of wiping off the residual of the photo-resist film 8 as shown in FIG. 7, directly depositing the metal layer 3 on the substrate 1 and the photo-resist film 8, and then wiping off the photo resist film 8 to form the gate electrode 2;

the photo-resist film 8 formed on the metal layer 3, using an ultraviolet light to expose the photo-resist film 8 through a photo mask having a predetermined pattern by projection manner, and then forming a pattern by developing, wiping off the metal around the slot 2a and the photo-resist film 8 to form the gate electrode 2.

The latter processes of producing the thin film transistor is shown in FIG 10 to FIG. 13 and FIG. 1.

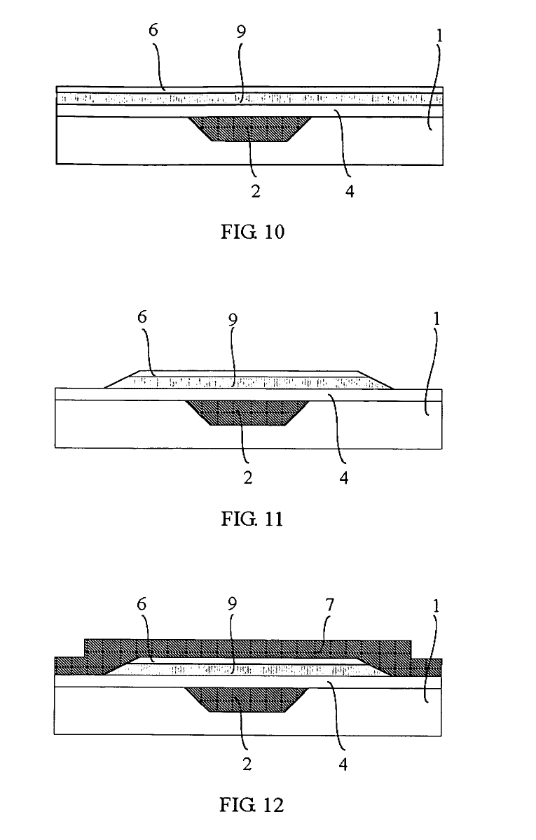

First, shown as FIG. 10, using chemical vapor deposition (CVD) to forming the gate insulation layer 4, wherein the reaction gases are silicon alkyl and ammonia. And then using a method of CVD to forming an amorphous silicon layer 9 on the insulation layer 4, wherein the reaction gases are silicon chloride and hydrogen. After that, forming a phosphor doped amorphous silicon layer 6 on the amorphous silicon layer 9 by doping technology.

Second, shown as FIG. 11, using photo mask process to etch two sides of the amorphous silicon layer 9 and the phosphor doped amorphous silicon layer 6 till showing up the gate insulation layer 4. Third, shown as FIG. 12, depositing a source and drain metal layer 7 on the phosphor amorphous layer 6 and the gate insulation layer 4.

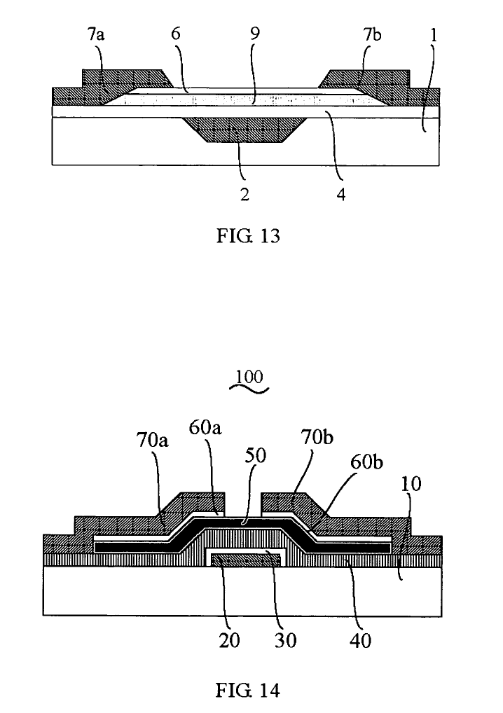

Subsequently, shown as FIG. 13, using photo mask process to etch the middle area of the source and drain metal layer 7 till showing up the amorphous silicon layer 6, and then forming a source electrode 7a and a drain electrode 7b.

Last, wiping off the middle area of the phosphor doped amorphous silicon layer 6 by a method of dry etching, and then forming a gate ohmic contact layer 6a, a drain ohmic contact layer 6b and a channel layer 5. That is, the TFT 100 as shown in FIG. 1 is produced.

And the section shape of the gate electrode 2 is not only trapezoid, further, its section shape is also rectangle.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A thin film transistor, comprising:
a substrate;
a gate electrode disposed in the substrate;
a gate insulation layer disposed on the substrate and gate electrode;
a channel layer disposed on the gate insulation layer;
a source ohmic contact layer and a drain ohmic contact layer arranged on the channel layer and at the end of the channel layer;
a source electrode disposed on the substrate and source ohmic contact layer;
a drain electrode disposed on the substrate and drain ohmic contact layer.

2. The thin film transistor of claim 1, wherein the surface of the gate electrode is parallel with the surface of the substrate.

3. The thin film transistor of claim 1, wherein the gate electrode is made of metal material.

4. The thin film transistor of claim 3, wherein the gate electrode adopts Cu, Al, Ti, Mo, Cr, Ta, Nd or its alloy.

5. The thin film transistor of claim 1, wherein the cross-section of the gate electrode is trapezoid.

6. The thin film transistor of claim 1, wherein the cross-section of the gate electrode is rectangle.

7. The thin film transistor of claim 1, wherein the substrate is made of one of glass, silicon oxide.

8. The thin film transistor of claim 1, wherein the gate insulation layer is made of one of silicon nitride, silicon oxide.

9. The thin film transistor of claim 1, wherein the channel layer is made of one of amorphous silicon, polycrystalline silicon.

10. The thin film transistor of claim 9, wherein the source and drain ohmic layers are formed by doping the channel layer.

11. A display device including a plurality of thin film transistor used to control and drive display material, wherein the thin film transistor comprising:
a substrate;
a gate electrode disposed in the substrate;
a gate insulation layer disposed on the substrate and gate electrode;
a channel layer disposed on the gate insulation layer;
a source ohmic contact layer and a drain ohmic contact layer arranged on the two sides of the channel layer;
a source electrode disposed on the substrate and source ohmic contact layer;
a drain electrode disposed on the substrate and drain ohmic contact layer.

12. The display device of claim 11, wherein the display material is liquid crystal.

13. A method for producing a thin film transistor comprising the steps of:
forming a gate electrode in a substrate by a photo mask process;
forming a gate insulation layer, amorphous silicon layer, phosphor doped amorphous silicon layer;
wiping off two sides of the amorphous silicon layer and phosphor doped amorphous silicon layer;
forming source and drain metal layers;
wiping off the center area of the metal layers;
wiping off the center area of the amorphous silicon layer to form a source ohmic contact layer, a drain ohmic contact layer and a channel layer.

14. The method for producing a thin film transistor of claim 13, wherein the method of forming the gate insulation layer, the amorphous silicon layer and the phosphor doped amorphous silicon layer is deposit.

15. The method for producing a thin film transistor of claim 13, wherein the method of wiping off the amorphous silicon layer and doping phosphor amorphous silicon layer is photo mask and etching.

16. The method for producing a thin film transistor of claim 13, wherein the method of forming the source and drain metal layer is deposit.

17. The method for producing a thin film transistor of claim 13, wherein the methods of wiping off the center area of the source and drain metal layer are photo mask and etching.

18. The method for producing a thin film transistor of claim 13, wherein the methods of wiping off the center area of the amorphous silicon layer and forming a source ohmic contact layer, a drain ohmic contact layer and a channel layer are dry etching.

19. The method for producing a thin film transistor of claim 13, wherein the once photo mask procedure of forming the gate electrode comprising the steps of:
forming a photo blocking film on the substrate;
forming a pattern of the gate electrode;
forming a channel on the substrate;
depositing metal in the channel;
forming the gate electrode.

20. The method for producing a thin film transistor of claim 19, wherein the method of forming the photo blocking film is covering and baking.

21. A thin film comprising:
a substrate defining a cavity in an upper face;
a gate electrode filled in said cavity;
a gate insulation layer applied upon said substrate covering both said substrate and said gate electrode;
a channel layer applied upon said gate insulation layer and only covering a central portion of an upper face of said gate insulation layer;
a source electrode disposed upon one side of said channel layer and further covering a portion of said gate insulation layer wherein said portion is exposed to an exterior before said source electrode is applied thereto; and
a drain electrode disposed upon the other side of the channel layer and further covering another portion of said gate insulation layer wherein said another portion is exposed to the exterior before said drain electrode is applied thereto.
